(19) United States
(12) Patent Application Publication
(10) Pub. No.: US 2016/0099192 A1
(43) Pub. Date: Apr. 7, 2016

(54) DUAL-SIDED RADIO-FREQUENCY PACKAGE HAVING BALL GRID ARRAY

(71) Applicant: SKYWORKS SOLUTIONS, INC., Woburn, MA (US)

(72) Inventors: Howard E. CHEN, Anaheim, CA (US); Robert Francis DARVEAUX, Gilbert, AZ (US); Matthew Sean READ, Rancho Santa Margarita, CA (US)

(21) Appl. No.: 14/815,426

(22) Filed: Jul. 31, 2015

Related U.S. Application Data
(60) Provisional application No. 62/031,815, filed on Jul. 31, 2014.
(60) Provisional application No. 62/031,816, filed on Jul. 31, 2014.

(51) Int. Cl. H01L 23/31; H01L 23/552; H05K 1/11; H05K 1/18; H05K 3/30

(52) U.S. Cl. CPC H01L 23/3128; H05K 1/181; H05K 3/303; H05K 1/11; H01L 23/552; H05K 2201/10734; H05K 2201/10515; H05K 2201/10522

(57) ABSTRACT

Dual-sided radio-frequency package having ball grid array. In some embodiments, a packaged radio-frequency (RF) device may include a packaging substrate configured to receive a plurality of components, the packaging substrate including a first side and a second side. The packaged RF device also includes a shielded package implemented on the first side of the packaging substrate, the shielded package including an RF circuit, the shielded package configured to provide RF shielding for at least a portion of the RF circuit. The packaged RF device further includes a ball-grid array (BGA) implemented on the second side of the packaging substrate, the BGA defining a mounting volume on the second side of the packaging substrate and a component implemented within the mounting volume.

### CROSS-REFERENCE TO RELATED APPLICATION(S)

This application claims priority to U.S. Provisional Patent Application No. 62/031,815 filed Jul. 31, 2014, entitled DUAL-SIDED RADIO-FREQUENCY PACKAGE HAVING BALL GRID ARRAY. This application also claims priority to U.S. Provisional Patent Application No. 62/031,816 filed Jul. 31, 2014, entitled DEVICES AND METHODS RELATED TO PROCESSING SINGULATED RADIO-FREQUENCY UNITS. The contents of each of the above-referenced application(s) are hereby expressly incorporated by reference herein in their entireties for all purposes.

### BACKGROUND

1. Field

The present disclosure relates to fabrication of packaged electronic modules such as radio-frequency (RF) modules.

2. Description of Related Art

In radio-frequency (RF) applications, RF circuits and related devices can be implemented in a packaged module. Such a packaged module can then be mounted on a circuit board such as a phone board.

### SUMMARY

In some implementations, the present disclosure relates to a packaged radio-frequency (RF) device including a packaging substrate configured to receive a plurality of components, the packaging substrate including a first side and a second side. The packaged RF device also includes a shielded package implemented on the first side of the packaging substrate, the shielded package including an RF circuit, the shielded package configured to provide RF shielding for at least a portion of the RF circuit. The packaged RF device further includes a ball-grid array (BGA) implemented on the second side of the packaging substrate, the BGA defining a mounting volume on the second side of the packaging substrate and a component implemented within the mounting volume.

In some embodiments, the first and second sides of the packaging substrate correspond to upper and lower sides, respectively, when the packaged RF device is oriented to be mounted on a circuit board.

In some embodiments, the BGA is configured to allow the packaged RF device to be mounted on the circuit board.

In some embodiments, the BGA includes a first group of solder balls arranged to partially or fully surround the component mounted on the lower side of the packaging substrate.

In some embodiments, the BGA further includes a second group of solder balls arranged to partially or fully surrounds the first group of solder balls.

In some embodiments, at least some of the first group of solder balls are electrically connected to input and output nodes of the RF circuit.

In some embodiments, the second group of solder balls are electrically connected to a ground plane within the packaging substrate.

In some embodiments, the first group of solder balls forms a rectangular perimeter around the component mounted on the lower side of the packaging substrate.

In some embodiments, the second group of solder balls forms a rectangular perimeter around the first group of solder balls.

In some embodiments, the packaging substrate includes a laminate substrate.

In some embodiments, the packaging substrate includes a ceramic substrate.

In some embodiments, the ceramic substrate includes a low-temperature co-fired ceramic (LTCC) substrate.

In some embodiments, the shielded package includes an overmold structure that substantially encapsulates the RF circuit.

In some embodiments, the shielded package further includes an upper conductive layer implemented on the overmold structure, the upper conductive layer electrically connected to a ground plane within the packaging substrate.

In some embodiments, the electrical connection between the upper conductive layer and the ground plane is achieved through one or more conductors within the overmold structure.

In some embodiments, the one or more conductors include shielding wirebonds arranged relative to the RF circuit to provide RF shielding functionality for at least a portion of the RF circuit.

In some embodiments, the one or more conductors include one or more SMT devices mounted on the packaging substrate, the one or more SMT devices arranged relative to the RF circuit to provide RF shielding functionality for at least a portion of the RF circuit.

In some embodiments, the electrical connection between the upper conductive layer and the ground plane is achieved through a conformal conductive coating implemented on one or more sides of the overmold structure.

In some embodiments, the conformal conductive coating extends to corresponding one or more sides of the packaging substrate.

In some embodiments, the packaging substrate includes one or more conductive features each having a portion exposed at the corresponding side of the packaging substrate to form an electrical connection with the conformal conductive coating, each conductive feature further connected to the conductive plane within the substrate packaging.

In some embodiments, the upper conductive layer is a conformal conductive layer.

In some embodiments, the conformal conductive layer substantially covers all four sides of the overmold structure and all four sides of the packaging substrate.

In some embodiments, the component includes an SMT device.

In some embodiments, the SMT device includes a passive device or an active RF device.

In some embodiments, the component includes a die.

In some embodiments, the die includes a semiconductor die.

In some embodiments, the semiconductor die is configured to facilitate processing of RF signals by the RF circuit.

In some implementations, the present disclosure relates to a method for manufacturing packaged radio-frequency (RF) devices. The method includes providing a packaging substrate configured to receive a plurality of components, the packaging substrate including a first side and a second side. The method also includes forming a shielded package on the first side of the packaging substrate, the shielded package including an RF circuit, the shielded package configured to provide RF shielding for at least a portion of the RF circuit. The method further includes mounting a component on the second side of the packaging substrate. The method further includes arranging a ball-grid array (BGA) on the second side of the packaging substrate such that the BGA is positioned relative to the component.

In some implementations, the present disclosure relates to a wireless device including a circuit board configured to receive a plurality of packaged modules. The wireless device also includes a shielded radio-frequency (RF) module mounted on the circuit board, the RF module including a packaging substrate configured to receive a plurality of components, the packaging substrate including a first side and a second side, the RF module further including a shielded package implemented on the first side of the packaging substrate, the shielded package including an RF circuit, the shielded package configured to provide RF shielding for at least a portion of the RF circuit, the RF module further including a ball-grid array (BGA) implemented on the second side of the packaging substrate, the BGA defining a mounting volume on the second side of the packaging substrate, the RF module further including a component implemented within the mounting volume.

In some implementations, the present disclosure relates to a method for manufacturing packaged radio-frequency (RF) devices. The method includes providing a packaging substrate panel an array of units, the packaging substrate panel including a first side and a second side. The method also includes forming a package on the first side of the packaging substrate panel to yield a packaged panel and such that each unit includes an RF circuit. The method further includes performing at least one processing operation on the second side of the packaging substrate to yield a dual-sided panel. The method further includes singulating the dual-sided panel to yield a plurality of individual dual-sided packages. The method further includes forming a conformal shielding layer for each of the individual dual-sided packages arranged in a frame such that a conformal shielding layer covers an upper surface and at least one side wall of the individual dual-sided package.

In some embodiments, the at least one processing operation on the second side includes mounting a component for each unit on the second side of the packaging substrate.

In some embodiments, the at least one processing operation on the second side further includes forming a ball-grid array (BGA) for each unit relative to the component on the second side of the packaging substrate.

In some embodiments, the conformal shielding layer covers substantially all of the side walls of the individual dual-sided package.

In some embodiments, the individual dual-sided packages are arranged in the frame such that the BGA and the component for each individual dual-sided package is within a corresponding aperture of the frame and a second-side periphery rests on a surface surrounding the aperture, to thereby expose the side walls.

In some embodiments, the BGA is held within the aperture by a tape.

In some embodiments, the forming of the conformal shielding layer includes a sputter deposition process.

In some embodiments, the frame has a rectangular shape configured to hold the individual dual-sided packages in a rectangular array.

In some embodiments, the frame has a wafer-like format suitable for the sputter deposition process.

In some embodiments, the individual dual-sided packages are arranged in a selected ring region on the wafer-like frame.

### BRIEF DESCRIPTION OF THE DRAWINGS

FIG. 1 shows a dual-sided package having a shielded package and a lower component mounted thereto, according to some embodiments of the present disclosure.

FIG. 2 shows that one or more lower components can be mounted under a shielded package, generally within a volume defined on an underside of the shielded package, according to some embodiments of the present disclosure.

FIG. 3 shows a shielded package can be a wire-shielded package, according to some embodiments of the present disclosure.

FIG. 4 shows that a shielded package can be a shielded package having a non-wire component that provides electrical connection between an upper conductive layer and a ground plane within a packaging substrate, according to some embodiments of the present disclosure.

FIG. 5 shows that in some embodiments, the shielded package can be a shielded package having a conformal conductive layer that is electrically connected to a ground plane within a packaging substrate, according to some embodiments of the present disclosure.

FIGS. 6A and 6B show an example of a BGA configuration that can be implemented, according to some embodiments of the present disclosure.

FIG. 7 shows that an under-fill can be provided between a lower component and an underside of a shielded package to which the lower component is mounted, according to some embodiments of the present disclosure.

FIG. 8 shows that a dual-sided package can include a plurality of lower components, according to some embodiments of the present disclosure.

FIGS. 9A-9E show various stages of a fabrication process in which substantially all of dual-sided features can be implemented in a panel format having an array of to-be-separated units, before such units are separated, according to some embodiments of the present disclosure.

FIGS. 10A-10D show various stages of a fabrication process in which a portion of the process is performed after individual units are singulated, according to some embodiments of the present disclosure.

FIG. 11 shows a frame carrier having a plate having an array of apertures, according to some embodiments of the present disclosure.

FIGS. 12A-12D show various states of a process that can be implemented to process individual units with a frame carrier, according to some embodiments of the present disclosure.

FIGS. 13A-13E show various example states leading to formation of dual-sided packages without conformal shielding, according to some embodiments of the present disclosure.

FIGS. 14A-14D show examples related to how conformal shielding can be formed for such dual-sided packages, according to some embodiments of the present disclosure. FIGS. 14E-14H show various states of a process that can be implemented to process individual units such as the un-shielded dual-sided packages with a frame carrier, according to some embodiments of the present disclosure.

FIG. 15 shows a dual-sided package including a shielded package having one or more surface-mount technology (SMT) devices mounted on a packaging substrate, according to some embodiments of the present disclosure.

FIG. 16 shows a dual-sided package that can be a more specific example of the dual-sided package of FIG. 15, according to some embodiments of the present disclosure.

FIG. 17 shows a dual-sided package that can be a more specific example of the dual-sided package of FIG. 16, according to some embodiments of the present disclosure.

FIG. 18 shows a dual-sided package having one or more features as described herein, implemented as a RF module, according to some embodiments of the present disclosure.

FIG. 19 depicts various features associated with the example wireless device, according to some embodiments of the present disclosure.

### DETAILED DESCRIPTION OF SOME EMBODIMENTS

The headings provided herein, if any, are for convenience only and do not necessarily affect the scope or meaning of the claimed invention

### Introduction

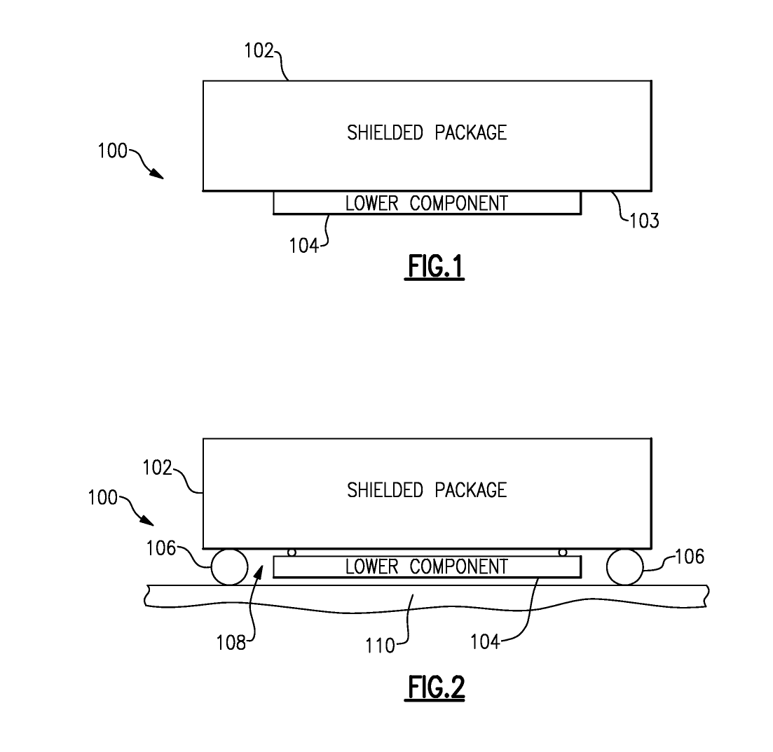

FIG. 1 shows a dual-sided package 100 having a shielded package 102 and a lower component 104 mounted thereto. For the purpose of description, a lower side of the shielded package 102 can include a side 103 of a packaging substrate that is to be mounted onto a circuit board such as a phone board. Although not shown separately in FIG. 1, it will be understood that the shielded package 102 can include such a packaging substrate and one or more upper components mounted on its upper side (when oriented as shown in FIG. 1). Accordingly, the dual-side property can include such upper component(s) mounted over the substrate and lower component(s) mounted under the substrate.

For the purpose of description, it will be understood that a lower component can include any device that can be mounted on the substrate and/or the circuit board. Such a device can be an active radio-frequency (RF) device or a passive device that facilitates processing of RF signals. By way of non-limiting examples, such a device can include a die such as a semiconductor die, an integrated passive device (IPD), a surface-mount technology (SMT) device, and the like. In some embodiments, the lower component as described herein can be electrically coupled to the one or more upper component through, for example, the substrate.

FIG. 2 shows that in some embodiments, one or more lower components can be mounted under a shielded package, generally within a volume defined on an underside of the shielded package. In FIG. 2, a volume 108 under a shielded package 102 is shown to be defined by the underside of the shielded package 102 and solder balls 106 of a ball grid array (BGA). The solder balls 106 are shown to allow the dual-sided package 100 to be mounted on a circuit board 110 such as a phone board. The solder balls 106 can be configured so that when mounted to the circuit board 110, there is sufficient vertical space between the upper surface of the circuit board 110 and the lower surface of the shielded package 102 for the lower component 104. Examples related to fabrication of dual-sided packages having such a configuration are described herein in greater detail. It will be understood that although such examples are described in the context of solder balls, other types of connection features that provide sufficient vertical space can also be utilized.

Examples of Dual-Sided Packages with BGA

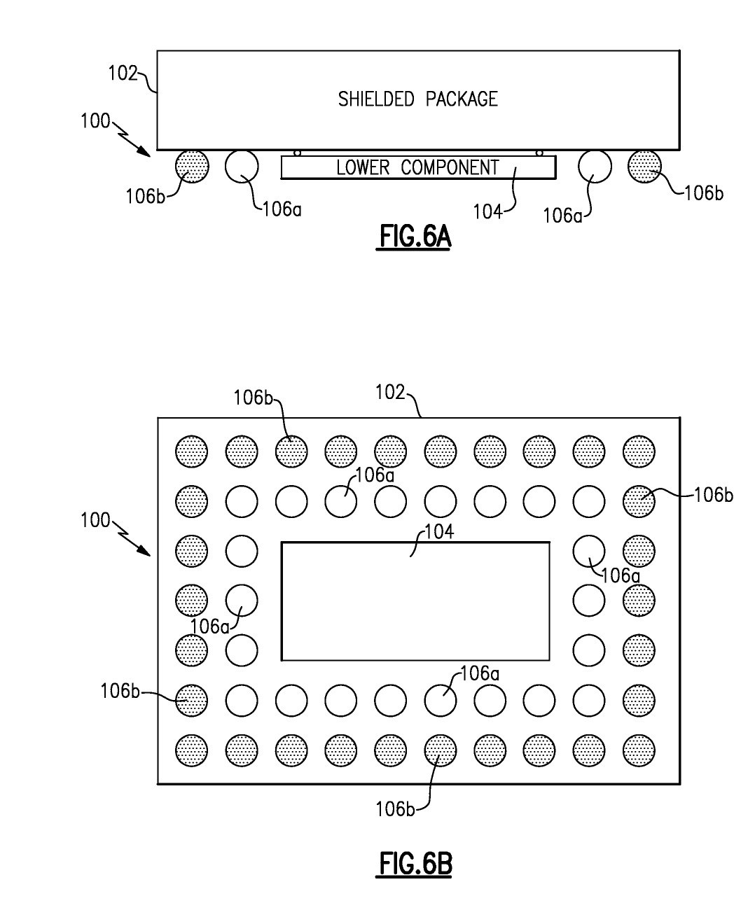

FIGS. 3-6 show non-limiting examples of dual-sided packages having BGAs. FIGS. 3-5 show examples of configurations of shielded packages that can be utilized. FIGS. 6A and 6B show an example of a BGA configuration that can be implemented.

FIG. 3 shows that in some embodiments, the shielded package 102 of FIG. 2 can be a wire-shielded package 120. The wire-shielded package 120 is shown to include a packaging substrate 122 (e.g., a laminate substrate) and a plurality of components mounted thereon. For example, a first component 124 is depicted as being mounted on the upper surface of the packaging substrate 122, and electrical connections between the component 124 and the packaging substrate 122 can be facilitated by, for example, wirebonds 128. In another example, a second component 126 is shown to be mounted on the upper surface of the packaging substrate 122 in a die-attach configuration. Electrical connections between the component 126 and the packaging substrate 122 can be facilitated by, for example, die-attach features.

In the example of FIG. 3, a plurality of shielding wires 130 (e.g. shielding wirebonds) are shown to be provided over the packaging substrate 122. Such shielding wires 130 can be electrically connected to a ground plane (not shown) within the packaging substrate 122. The shielding wires 130 as well as the mounted components 124, 126 are shown to be encapsulated by an overmold 132. The upper surface of the overmold 132 can be configured to expose the upper portions of the shielding wires 130, and an upper conductive layer 134 can be formed thereon. Accordingly, a combination of the upper conductive layer 134, the shielding wires 130, and the ground plane can define a shielded volume or region. Such a configuration can be implemented to provide shielding functionality between regions within and outside of the shielded package 120, and/or between regions that are both within the shielded package 120. Additional details concerning such shielding can be found in, for example, U.S. Pat. No. 8,373,264 entitled SEMICONDUCTOR PACKAGE WITH INTEGRATED INTERFERENCE SHIELDING AND METHOD OF MANUFACTURE THEREOF which is expressly incorporated by reference in its entirety for all purposes.

In the example of FIG. 3, an array of solder balls 106 is shown to be implemented on the underside of the packaging substrate 122 so as to define an underside volume. A lower component 104 is shown to be mounted within such an underside volume to thereby form a dual-sided package 100. In FIG. 3, the dual-sided package 100 is shown to be mounted on a circuit board 110 such as a phone board.

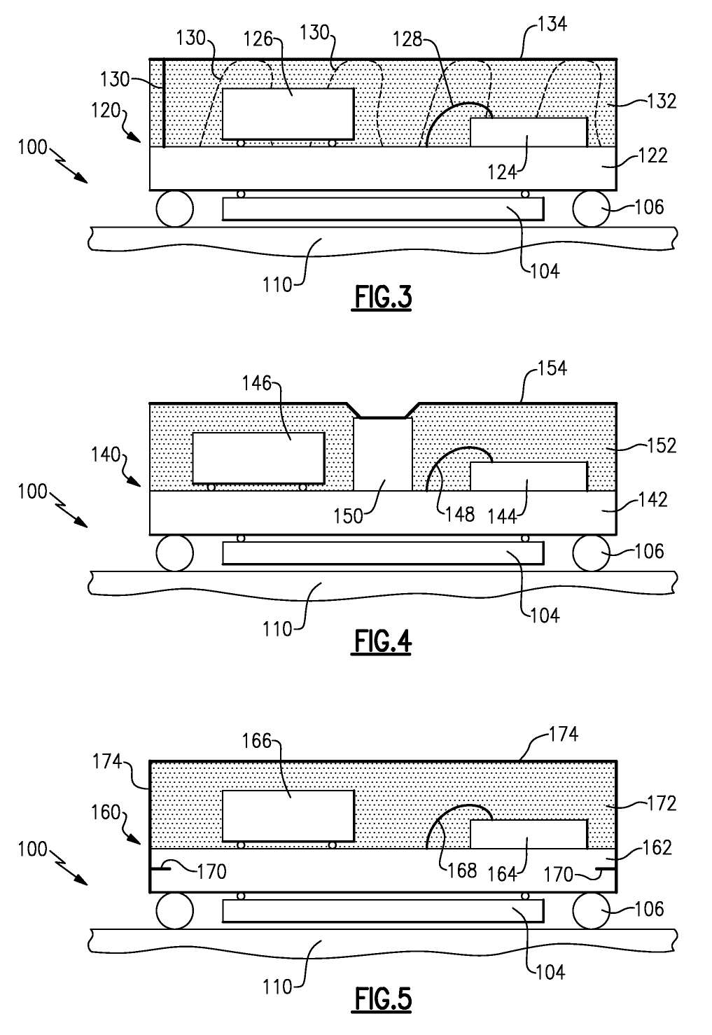

FIG. 4 shows that in some embodiments, the shielded package 102 of FIG. 2 can be a shielded package 140 having a non-wire component 150 that provides electrical connection between an upper conductive layer 154 and a ground plane (not shown) within a packaging substrate 142 (e.g., a laminate substrate). In addition to the component 150, the packaging substrate 142 is shown to have a plurality of components mounted thereon. For example, a first component 144 is depicted as being mounted on the upper surface of the packaging substrate 142, and electrical connections between the component 144 and the packaging substrate 142 can be facilitated by, for example, wirebonds 148. In another example, a second component 146 is shown to be mounted on the upper surface of the packaging substrate 142 in a die-attach configuration. Electrical connections between the component 146 and the packaging substrate 142 can be facilitated by, for example, die-attach features.

In the example of FIG. 4, the component 150 is shown to provide an electrical connection between the upper conductive layer 154 and the ground plane (not shown) within the packaging substrate 142. The component 150 as well as the mounted components 144, 146 are shown to be encapsulated by an overmold 152. The upper surface of the overmold 152 can be configured to expose the upper portion of the component 150, and the upper conductive layer 154 can cover such an exposed portion as well as the remaining upper surface of the overmold 152. Accordingly, a combination of the upper conductive layer 154, the component 150, and the ground plane can define a shielded volume or region. Such a configuration can be implemented to provide shielding functionality between regions within and outside of the shielded package 140, and/or between regions that are both within the shielded package 140. Additional details concerning such shielding can be found in, for example, U.S. patent application Ser. No. 14/252,719 filed on Apr. 14, 2014, entitled APPARATUS AND METHODS RELATED TO CONFORMAL COATING IMPLEMENTED WITH SURFACE MOUNT DEVICES, which is expressly incorporated by reference in its entirety.

In the example of FIG. 4, an array of solder balls 106 is shown to be implemented on the underside of the packaging substrate 142 so as to define an underside volume. A lower component 104 is shown to be mounted within such an underside volume to thereby form a dual-sided package 100. In FIG. 4, the dual-sided package 100 is shown to be mounted on a circuit board 110 such as a phone board.

FIG. 5 shows that in some embodiments, the shielded package 102 of FIG. 2 can be a shielded package 160 having a conformal conductive layer 174 that is electrically connected to a ground plane (not shown) within a packaging substrate 162 (e.g., a laminate substrate or a ceramic substrate). The packaging substrate 162 is shown to have a plurality of components mounted thereon. For example, a first component 164 is depicted as being mounted on the upper surface of the packaging substrate 162, and electrical connections between the component 164 and the packaging substrate 162 can be facilitated by, for example, wirebonds 168. In another example, a second component 166 is shown to be mounted on the upper surface of the packaging substrate 162 in a die-attach configuration. Electrical connections between the component 166 and the packaging substrate 162 can be facilitated by, for example, die-attach features.

In the example of FIG. 5, the mounted components 164, 166 are shown to be encapsulated by an overmold 172. The conformal conductive layer 174 is shown to generally cover the upper surface of the overmold 172, as well as side walls (e.g., all four side walls) defined by the sides of the overmold 172 and the packaging substrate 162. The packaging substrate 162 is shown to include conductive features 170 having portions exposed on the sides of the packaging substrate, and also electrically connected to the ground plane (not shown), to thereby provide electrical connections between the conformal conductive layer 174 and the ground plane. Accordingly, a combination of the conformal conductive layer 174 and the ground plane can define a shielded volume or region. Such a configuration can be implemented to provide shielding functionality on one or more sides of the shielded package 160. Additional details concerning such shielding can be found in, for example, U.S. patent application Ser. No. 14/528,447 filed on Oct. 30, 2014, entitled DEVICES AND METHODS RELATED TO PACKAGING OF RADIO-FREQUENCY DEVICES ON CERAMIC SUBSTRATES, which is also expressly incorporated by reference in its entirety for all purposes. In some embodiments, the overmold 172 may not be present (e.g., the overmold 172 may be optional). For example, when the packaging substrate 162 is a ceramic substrate, the overmold 172 may not be present.

In the example of FIG. 5, an array of solder balls 106 is shown to be implemented on the underside of the packaging substrate 162 so as to define an underside volume. A lower component 104 is shown to be mounted within such an underside volume to thereby form a dual-sided package 100. In FIG. 5, the dual-sided package 100 is shown to be mounted on a circuit board 110 such as a phone board.

In the examples of FIGS. 3-5, the solder balls 106 are depicted as being implemented in a single row that forms a perimeter at an underside of the shielded package. If such solder balls are utilized as input and/or output for processing of radio-frequency (RF) signals, it may be desirable to provide shielding between such input/output solder balls and locations outside of the dual-sided package 100. Furthermore, it shall be understood that in other embodiments, any of the shielding features of FIGS. 3, 4, and/or 5 may be combined. For example, two or more of the shielding wires 130 illustrated in FIG. 3, the component 150 illustrated in FIG. 4, and the conformal conductive layer 174 illustrated in FIG. 5, may be combined.

FIGS. 6A and 6B show side and underside views of a dual-sided package 100 configured to provide such shielding functionality. In the example of FIGS. 6A and 6B, two rows of solder balls can be implemented. The inner row of solder balls 106a can be utilized for input and/or output of RF signals, or for any other input/output where shielding is desired. The outer row of solder balls 106b can be utilized for, for example, grounding of the dual-sided package 100, and can be electrically connected to the ground plane of the shielded package 102. Accordingly, the outer row of solder balls 106b can provide shielding for the inner row of solder balls 106a. The outer row of solder balls 106b can also provide shielding for the lower component 104.

In the example of FIGS. 6A and 6B, each of the inner and outer rows of solder balls 106a, 106b is shown to form a full perimeter on the underside of the shielded package 102. However, it will be understood that either or both of the inner and outer rows of solder balls 106a, 106b can form partial perimeter(s) as needed or desired to achieve desired functionalities. For example, if shielding is desired on only one side, a full perimeter of the outer row of solder balls 106b may not be needed. Accordingly, one or more sides of outer row of solder balls 106b can be implemented to provide such shielding functionality. In another example, input/output connections (e.g., RF input/output, control signals, power) may not need a full perimeter of inner row of solder balls 106a. Accordingly, the inner row of solder balls 106a can form a partial perimeter on the underside of the shielded package 102.

### Examples of Additional Features in Dual-Sided Packages

FIG. 7 shows that in some embodiments, an under-fill can be provided between a lower component and an underside of a shielded package to which the lower component is mounted. In FIG. 7, a dual-sided package 100 is similar to the BGA-based example of FIG. 2. An under-fill 230 is shown to be provided between a lower component 104 and the underside of a shielded package 102. Such an under-fill structure can provide a more secure mounting of the lower component 104.

FIG. 8 shows that in some embodiments, a dual-sided package can include a plurality of lower components. In FIG. 8, a dual-sided package 100 is similar to the BGA-based example of FIG. 2. The dual-sided package 100 is shown to include two lower components 104a, 104b mounted to the underside of a shielded package 102.

Other additional features, variations, or any combination thereof, can be also be implemented.

### Examples Related to Fabrication of Dual-Sided Packages

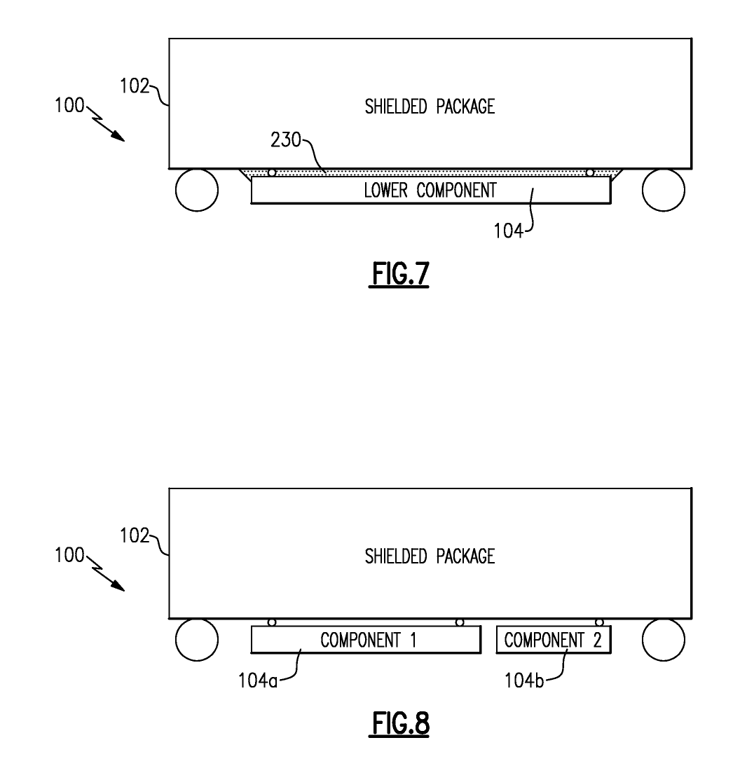

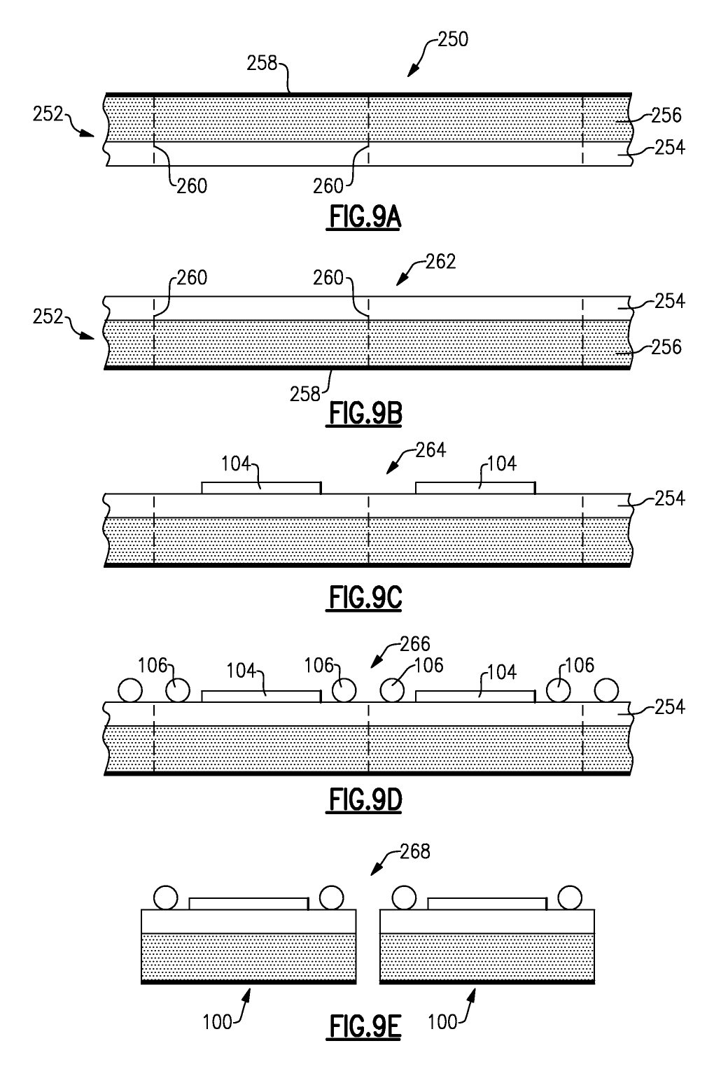

FIGS. 9-12 show examples of how dual-sided packages can be fabricated. As described herein, such examples can facilitate mass-production of dual-sided packages.

FIGS. 9A-9E show various stages of a fabrication process in which substantially all of dual-sided features can be implemented in a panel format having an array of to-be-separated units, before such units are separated (also referred to as singulated). Although described in the context of BGA-based dual-sided packages, it will be understood that one or more features of the fabrication technique of FIGS. 9A-9E can also be implemented for fabrication of dual-sided packages having other types of mounting features. In some implementations, the fabrication process of FIGS. 9A-9E can be utilized for manufacturing of dual-sided packages described herein in reference to, for example, FIGS. 3 and 4.

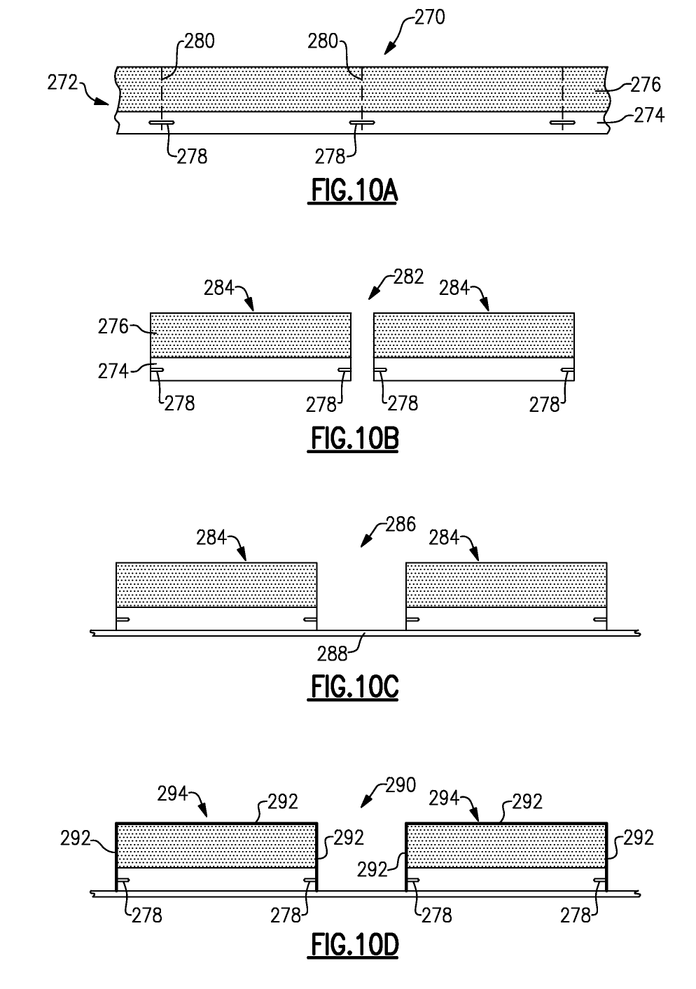

FIGS. 10A-10D show various stages of a fabrication process in which a portion of the process is performed after individual units are singulated. Although described in the context of BGA-based dual-sided packages, it will be understood that one or more features of the fabrication technique of FIGS. 10A-10D can also be implemented for fabrication of dual-sided packages having other types of mounting features. In some implementations, the fabrication process of FIGS. 10A-10D can be utilized for manufacturing of dual-sided packages described herein in reference to, for example, FIG. 5.

Referring to FIG. 9A, a fabrication state 250 can include a panel 252 having a plurality of to-be-singulated units. For example, singulation can occur at boundaries depicted by dashed lines 260 so at to yield singulated individual units. The panel 252 is shown to include a substrate panel 254 on which upper portions (collectively indicated as 256) are formed. Each unit of such an upper-portion panel can include various parts described herein in reference to FIGS. 3, 4, and/or 5. For example, each unit of such an upper-portion panel may include shielding features of FIGS. 3, 4, and/or 5. Such parts can include various components and shielding structures mounted or implemented on the substrate panel 254. The upper-portion panel 256 can also include an overmold layer which can be formed as a common layer for a number of individual units. Similar to the common overmold layer, an upper conductive layer 258 can be formed to cover a number of individual units.

Referring to FIG. 9B, a fabrication state 262 can include the panel 252 of FIG. 9A being inverted so that its underside faces upward. Such an inverted orientation can allow processing of the underside while the individual units are still attached in the panel.

Referring to FIG. 9C, a fabrication state 264 can include a lower component 104 being attached for each unit on the underside (which is facing upward) of the substrate 254. Referring to FIG. 9D, a fabrication state 266 can include an array of solder balls 106 being formed for each unit on the underside (which is facing upward) of the substrate 254. Such a step is shown to yield an array of dual-sided units to be singulated. It will be understood that the fabrication state 266 can occur before or after the fabrication step 264.

Referring to FIG. 9E, a fabrication state 268 can include individual units being singulated to yield a plurality of dual-sided packages 100 substantially ready to be mounted to circuit boards. It will be understood that such a singulation process can be achieved while the panel (252) is in its inverted orientation (as shown in the example of FIG. 9E), or while the panel (252) is in its upright orientation (e.g., as in the example of FIG. 9A).

As described herein, such processing of most or all of upper and lower sides of a substrate panel can be achieved since the side walls of the dual-sided packages are not utilized for shielding. However, when one or more side walls include shielding features, at least some of processing related to shielding need to be implemented with the corresponding side walls exposed. In some embodiments (e.g., where all four side walls include shielding features), at least some processing need to be performed on singulated units.

FIGS. 10A-10D show various states of a process that can be implemented to yield singulated units having some or all side walls with shielding features. Referring to FIG. 10A, a fabrication state 270 can include a panel 272 having a plurality of to-be-singulated units. For example, singulation can occur at boundaries depicted by dashed lines 280 so at to yield singulated individual units. The panel 272 is shown to include a substrate panel 274 on which upper portions (collectively indicated as 276) are formed. Each unit of such an upper-portion panel can include various parts described herein in reference to FIG. 5. Such parts can include various components mounted or implemented on the substrate panel 274. The upper-portion panel 276 can also include an overmold layer which can be formed as a common layer for a number of individual units.

In the example of FIG. 10A, conductive features 278 are shown to be implemented within the substrate panel 274. Each conductive feature 278 can straddle the corresponding boundary 280, such than when separation occurs at the boundary 280, each of the two exposed side walls of the substrates includes an exposed portion of the conductive feature 278 that has been cut. Each of such cut conductive feature is electrically connect to a ground plane (not shown) within the corresponding substrate.

Referring to FIG. 10B, a fabrication state 282 can include a plurality of individual units 284 resulting from singulations along the boundary lines (280 in FIG. 10A). As described above, each of the individual units 284 includes side walls; and each side wall is shown to include an exposed portion of the cut conductive feature 278.

Referring to FIG. 10C, a fabrication state 286 can include the individual units 284 being positioned for formation of a conformal conductive layer. In some embodiments, the individual units 284 can be mounted on a tape 288 to be temporarily held in place during the formation of the conformal conductive layer. The individual units 284 can be positioned with sufficient spacing to allow effective formation of the conformal conductive layer on the side walls.

Referring to FIG. 10D, a fabrication state 290 can include formation of a conformal conductive layer 292 on the upper surface and the side surfaces of each of the individual units (284 in FIG. 10C) mounted on the tape 288. The conductive layer 292, in combination with the ground plane (connected through the conductive features 278) provides shielding functionality for a volume generally contained therein. In the example of FIG. 10D, each of the resulting individual units 294 can be the shielded package described in reference to FIG. 5.

### Examples Related to Processing of Individual Units

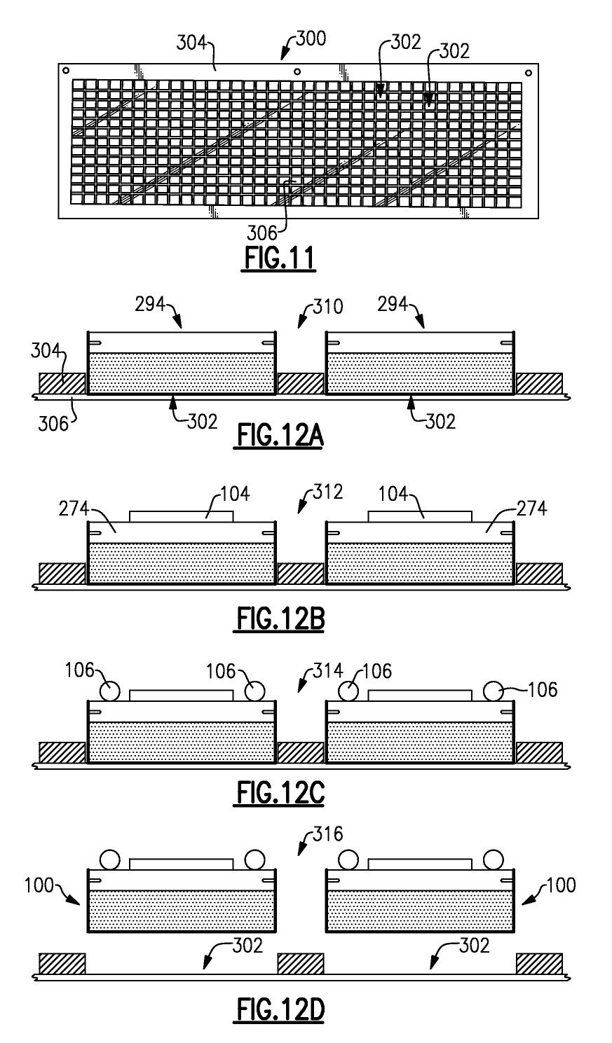

In the examples described in reference to FIGS. 9A-9E, substantially all steps in fabrication of dual-sided packages can be performed in a panel format before individual units are singulated. For the examples of FIGS. 10A-10D, the side coverage of the conformal conductive layer on each unit necessitates that at least some steps be performed after the singulation step. FIGS. 11 and 12 show examples where a plurality of individual units can be processed together in an array. Although described in the context of fabricating dual-sided packages, it will be understood that one or more features related to the examples of FIGS. 11 and 12 can be utilized in other applications, including fabrication of single-sided packages.

FIG. 11 shows a frame carrier 300 having a plate 304 having an array of apertures 302. Each of such apertures can be dimensioned to receive an individual unit, such that a plurality of such individual units can be arranged in an array for further processing. In FIG. 11, a tape 306 is shown to be provided underneath the frame carrier 300, such that an adhesive side engages the plate 304 and the apertures 302 exposes the corresponding portions of the adhesive side. Thus, an individual unit positioned in an aperture 302 can be temporarily held in place by the adhesive. Additional details concerning the frame carrier 300 are described in, for example, U.S. patent application Ser. No. 14/710,114 filed on May 12, 2015, entitled DEVICES AND METHODS FOR PROCESSING SINGULATED RADIO-FREQUENCY UNITS, which is also expressly incorporated by reference in its entirety for all purposes.

FIGS. 12A-12D show various states of a process that can be implemented to process individual units such as the individual units 294 of FIG. 10D with the frame carrier 300 of FIG. 11. Referring to FIG. 12A, a fabrication state 310 can include a plurality of individual units 294 being positioned in their respective apertures 302 defined in a plate 304 and temporarily held in place by a tape 306. Once the individual units are arranged in such a manner, some or all of the subsequent steps can be performed in manners as if the units are in a panel format.

For example, and referring to FIG. 12B, a fabrication state 312 can include a lower component 104 being attached on the underside of the substrate 274 of each unit. Referring to FIG. 12C, a fabrication state 314 can include an array of solder balls 106 being formed on the underside of the substrate 274 of each unit. Such a step is shown to yield an array of individual dual-sided units.

Referring to FIG. 12D, a fabrication state 316 can include the dual-sided packages 100 being removed from the tape 306 and their respective apertures 302. In some embodiments, such removal of the dual-sided packages from the tape 306 can be achieved as described in, for example, U.S. patent application Ser. No. 14/710,114 filed on May 12, 2015, entitled DEVICES AND METHODS FOR PROCESSING SINGULATED RADIO-FREQUENCY UNITS.

### Examples Related to Use of Frame Carriers for Conformal Coating

In the examples described herein in reference to FIGS. 10-12, units that will become conformal-shielded dual-sided packages can be singulated prior to process steps (e.g., mounting of a lower component and formation of a BGA) being performed on the underside of a packaging substrate.

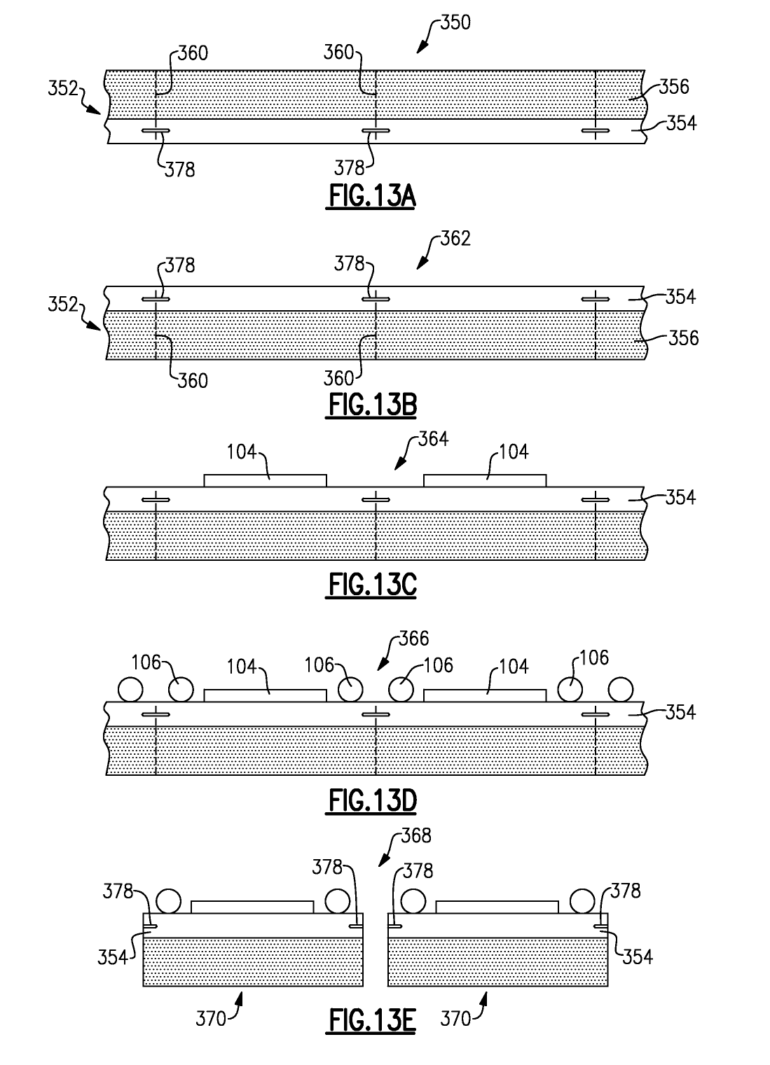

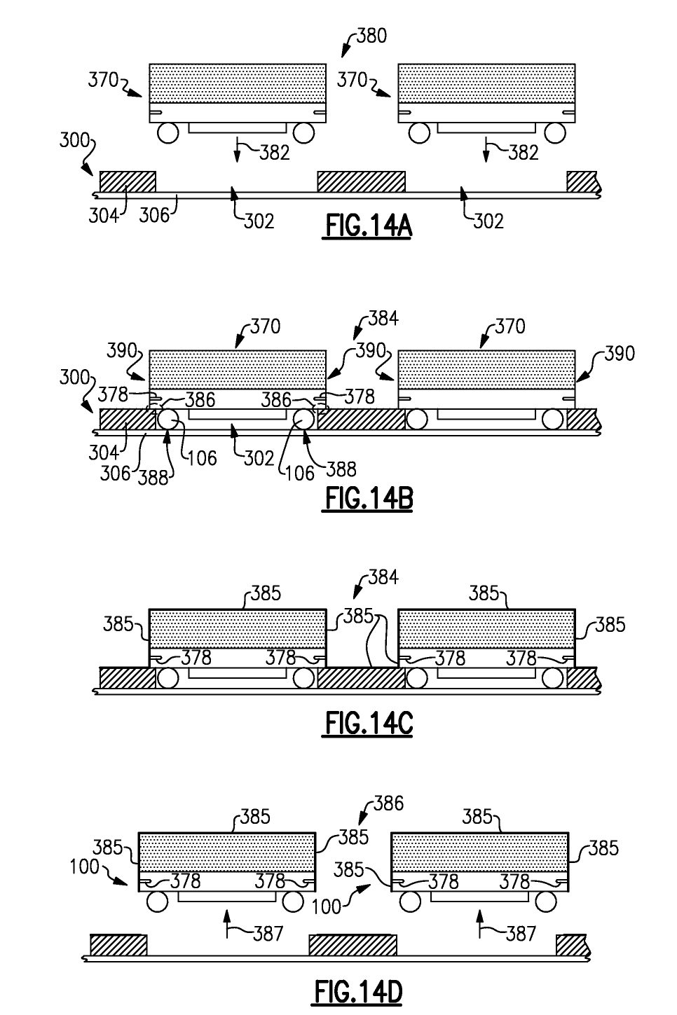

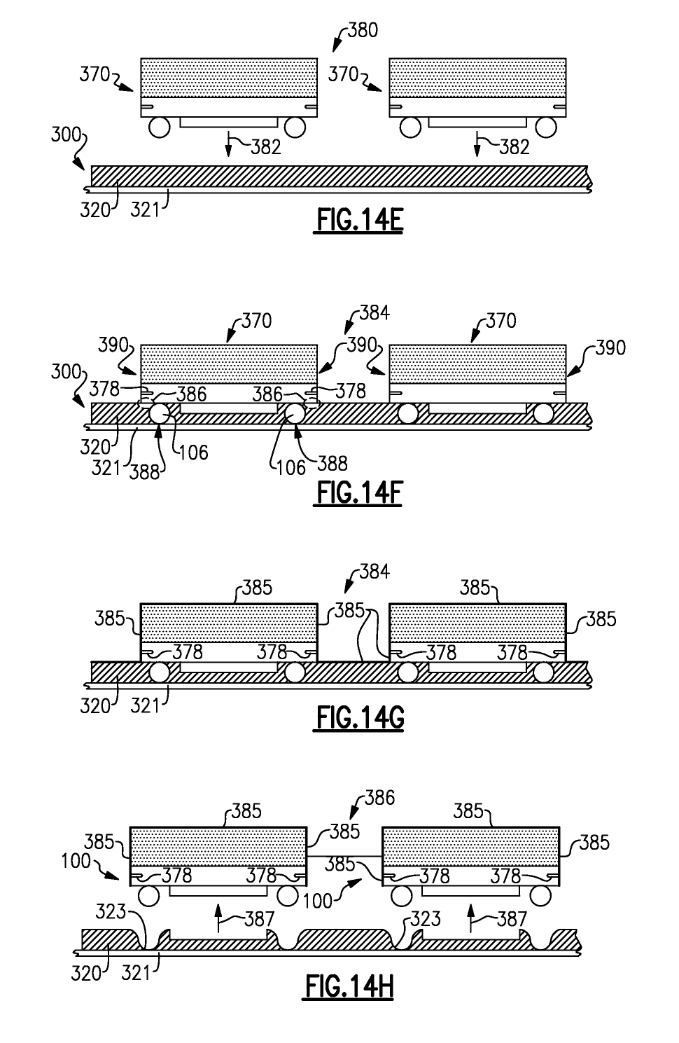

FIGS. 13 and 14 show examples related to an alternate process for manufacturing conformal-shielded dual-sided packages. In such a process, singulation can be performed after process steps (e.g., mounting of a lower component and formation of a BGA) are performed on the underside of a packaging substrate. More particularly, FIGS. 13A-13E show various example states leading to formation of dual-sided packages without conformal shielding. FIGS. 14A-14D show examples related to how conformal shielding can be formed for such dual-sided packages.

In some embodiments, the examples process steps of FIGS. 13A-13E can be similar to the examples of FIGS. 9A-9E, but without the conductive layer (258). Referring to FIG. 13A, a fabrication state 250 can include a panel 352 having a plurality of to-be-singulated units. For example, singulation can occur at boundaries depicted by dashed lines 360 so at to yield singulated individual units. The panel 352 is shown to include a substrate panel 354 on which upper portions (collectively indicated as 356) are formed. Each unit of such an upper-portion panel can include various parts described herein in reference to FIG. 5. Such parts can include various components and shielding structures mounted or implemented on the substrate panel 354. The upper-portion panel 356 can also include an overmold layer which can be formed as a common layer for a number of individual units.

Referring to FIG. 13B, a fabrication state 362 can include the panel 352 of FIG. 13A being inverted so that its underside faces upward. Such an inverted orientation can allow processing of the underside while the individual units are still attached in the panel.

Referring to FIG. 13C, a fabrication state 364 can include a lower component 104 being attached for each unit on the underside (which is facing upward) of the substrate 354. Referring to FIG. 13D, a fabrication state 366 can include an array of solder balls 106 being formed for each unit on the underside (which is facing upward) of the substrate 354. Such a step is shown to yield an array of un-shielded dual-sided units to be singulated. It will be understood that the fabrication state 366 can occur before or after the fabrication step 364.

Referring to FIG. 13E, a fabrication state 368 can include individual units being singulated to yield a plurality of un-shielded dual-sided packages 370 substantially ready for conformal shielding process steps, or if shielding is not needed, substantially ready to be mounted to circuit boards. In some embodiments, such a singulation process can be achieved while the panel (352) is in its inverted orientation (as shown in the example of FIG. 13E).

FIGS. 14A-14D show various states of a process that can be implemented to process individual units such as the un-shielded dual-sided packages 370 of FIG. 13D with a frame carrier 300. Referring to FIG. 14A, a fabrication state 380 can include a plurality of un-shielded dual-sided packages 370 being positioned (arrow 382) partially in their respective apertures 302 defined in a plate 304 and temporarily held in place by a tape 306.

Referring to FIG. 14B, a fabrication state 384 can include the un-shielded dual-sided packages 370 positioned partially in their respective apertures 302. Each aperture 302 is shown to have lateral dimensions to allow the solder balls 106 to be generally within the aperture 302, but have the underside periphery of the packaging substrate engage the upper surface of the plate 304. Such an engagement between the underside of the packaging substrate and the plate 304 is indicated as 386.

In some embodiments, the thickness of the plate 304 can be selected so that when the un-shielded dual-sided packages 370 is positioned as shown in FIG. 14B, bottom surfaces of the solder balls 106 engage a tape 306. Such an engagement between the solder balls 106 and the tape 306 is indicated as 388.

Once the individual un-shielded dual-sided packages 370 are arranged in such a manner, some or all of the subsequent steps can be performed in manners as if the units are in a panel format. Advantageously, such steps can include formation of a conformal shielding layer on the upper surface and the side walls (390) of each un-shielded dual-sided package 370. More particularly, and as described herein, the position of the un-shielded dual-sided package 370 relative to the plate 304 allows the side walls 390 to be exposed substantially fully for metal deposition by techniques such as sputter deposition. As further shown in FIG. 14B, the apertures 302 of the plate 304 can be arranged so that the un-shielded dual-sided packages 370 positioned therein are spaced apart sufficiently to facilitate effective sputter deposition of metal on the side walls 390.

FIG. 14C shows a fabrication state 384 where a conformal conductive layer 385 has been formed. Such a conformal conductive layer 385 is shown to cover the upper surface and the side walls (390) of each dual-sided package. The side wall portion of the conformal conductive layer 385 is further shown to be in electrical contact with the conductive features 378 (which are in turn connected to a ground plane (not shown)) to thereby form an RF shield for the dual-sided package.

In examples where sputter deposition is utilized, the conductive layer 385 can also be formed on the exposed surface of the plate 304 (e.g., between the dual-sided packages). To avoid or limit the build-up of such a layer on the plate 304, various techniques can be utilized. For example, a sacrificial film with appropriate cutouts for the apertures 302 can be provided on the receiving surface of the plate 304. Once sufficient amount of metal has been deposited on the film, it can be discarded, and a new film can be used. In another example, build-up of metal layer on the receiving surface of the plate 304 can be removed periodically or as needed.

FIG. 14D shows a fabrication state 386 where shielded dual-sided packages 100 are being removed (arrow 387) from the frame carrier 300. Thus, one can see that the resulting dual-sided packages 100 with conformal shielding can be obtained by different processes. For example, the dual-sided packages 100 with conformal shielding as described in reference to FIG. 12D are similar to the dual-sided packages 100 (with conformal shielding) of FIG. 14D. Accordingly, it will be understood that other variations in process steps can be implemented.

FIGS. 14E-14H show various states of a process that can be implemented to process individual units such as the un-shielded dual-sided packages 370 of FIG. 13D with a frame carrier 300. Referring to FIG. 14E, a fabrication state 380 can include a plurality of un-shielded dual-sided packages 370 being positioned (arrow 382) over an adhesive layer 320. Examples of the adhesive layer 320 may include a layer of glue, a layer of paste, a layer of epoxy/epoxy resin, etc. The adhesive layer 320 may be deposited over a surface 321 of the frame carrier 300 (e.g., an upper surface of the frame carrier 300).

Referring to FIG. 14F, a fabrication state 384 can include the un-shielded dual-sided packages 370 positioned such that the solder balls 106 engage (e.g., are in contact with) the surface 321. In some embodiments, the thickness of the adhesive layer 320 can be selected so that when the un-shielded dual-sided packages 370 is positioned as shown in FIG. 14B, bottom surfaces of the solder balls 106 engage the surface 321. Such an engagement between the solder balls 106 and the surface 321 is indicated as 388. As illustrated in FIG. 14F, the underside periphery of the packaging substrate may engage adhesive layer 320 (e.g., may contact the adhesive layer 320). Such an engagement between the underside of the packaging substrate and the adhesive layer 320 is indicated as 386.

Once the individual un-shielded dual-sided packages 370 are arranged in such a manner, some or all of the subsequent steps can be performed in manners as if the units are in a panel format. Advantageously, such steps can include formation of a conformal shielding layer on the upper surface and the side walls (390) of each un-shielded dual-sided package 370. More particularly, and as described herein, the position of the un-shielded dual-sided package 370 relative to the plate 304 allows the side walls 390 to be exposed substantially fully for metal deposition by techniques such as sputter deposition. As further shown in FIG. 14F, the un-shielded dual-sided packages 370 can be arranged so that the un-shielded dual-sided packages 370 positioned therein are spaced apart sufficiently to facilitate effective sputter deposition of metal on the side walls 390.

FIG. 14G shows a fabrication state 384 where a conformal conductive layer 385 has been formed. Such a conformal conductive layer 385 is shown to cover the upper surface and the side walls (390) of each dual-sided package. The side wall portion of the conformal conductive layer 385 is further shown to be in electrical contact with the conductive features 378 (which are in turn connected to a ground plane (not shown)) to thereby form an RF shield for the dual-sided package.

FIG. 14H shows a fabrication state 386 where shielded dual-sided packages 100 are being removed (arrow 387) from the frame carrier 300. Thus, one can see that the resulting dual-sided packages 100 with conformal shielding can be obtained by different processes. For example, the dual-sided packages 100 with conformal shielding as described in reference to FIG. 12D are similar to the dual-sided packages 100 (with conformal shielding) of FIG. 14H. Accordingly, it will be understood that other variations in process steps can be implemented.

As illustrated in FIG. 14H, indentations 323 may be present in the adhesive layer 320 (e.g., semi-circle indentations and/or rectangular indentations) after the shielded dual-sided packages 100 are removed from the adhesive layer 320 and/or the frame carrier 300. The indentations 323 may be formed, caused, and/or created by the solder balls 106, the underside of the shielded dual-sided packages 100, and/or components mounted on the underside of the shielded dual-sided packages 100. In one embodiment, portions of the adhesive layer 320 may remain attached (e.g., may stick) to the shielded dual-sided packages 100 when the shielded dual-sided packages 100 are removed (not shown in the figures). The portions of the adhesive layer 320 that remain attached to the shielded dual-sided packages 100 may be removed in a later process. For example, the portions of the adhesive layer 320 that remain attached to the shielded dual-sided packages 100 may be removed during a cleaning process.

### Examples of Products Related to Dual-Sided Packages

As described herein, a shielded package and a lower component of a dual-sided package can include different combinations of components. FIG. 15 shows that in some embodiments, a dual-sided package 100 can include a shielded package 102 having one or more surface-mount technology (SMT) devices 400 mounted on a packaging substrate 402. As further shown in FIG. 15, one or more semiconductor die 104 can be mounted under the packaging substrate 402. As described herein, such one or more die can be mounted within a region generally defined by an array of solder balls 106.

As further described herein, an overmold 404 can be formed over the packaging substrate 402 so as to substantially encapsulate the SMT device(s) 404, and to facilitate shielding functionalities. It will be understood that the shielded package 102 can include one or more shielding features as described herein.

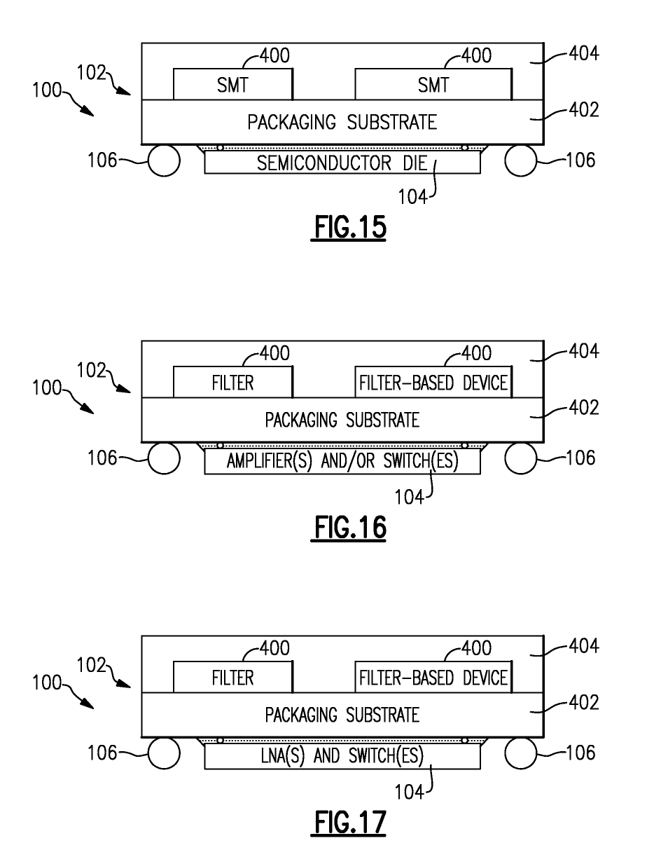

FIG. 16 shows a dual-sided package 100 that can be a more specific example of the dual-sided package of FIG. 15. In the example of FIG. 16, the SMT device(s) can be one or more filters and/or filter-based devices 400 that are encapsulated by an overmold 404. Further, the semiconductor die mounted under a packaging substrate 402 can be a die having RF amplifier(s) and/or switch(es). Accordingly, such a dual-side package can be implemented as different modules configured to facilitate transmission and/or reception of RF signals. For example, the dual-sided package 100 can be implemented as a power amplifier (PA) module, a low-noise amplifier (LNA) module, a front-end module (FEM), a switching module, etc.

FIG. 17 shows a dual-sided package 100 that can be a more specific example of the dual-sided package of FIG. 16. In the example of FIG. 17, the semiconductor die mounted under a packaging substrate 402 can be a die having one or more LNAs and one or more switches. In some embodiments, such a dual-side package can be implemented as a module having LNA-related functionalities, including, for example, an LNA module.

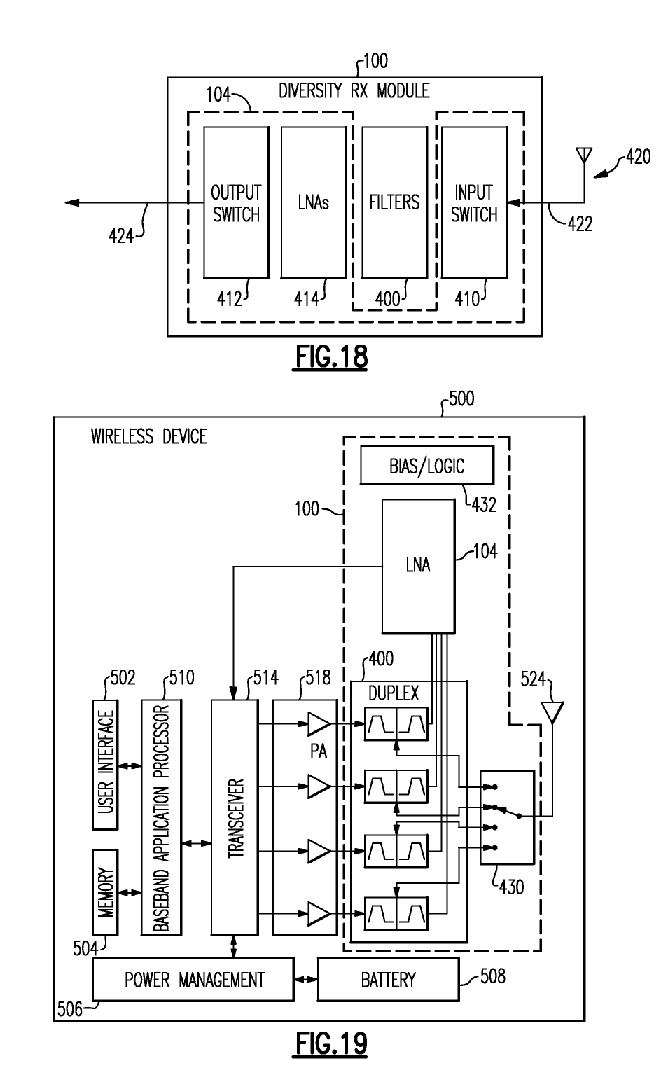

FIGS. 18 and 19 show examples of how the dual-sided package 100 of FIG. 17 can be implemented in wireless devices. FIG. 18 shows that in some embodiments, a dual-sided package having one or more features as described herein can be implemented as a diversity receive (RX) module 100. Such a module can be implemented relatively close to a diversity antenna 420 so as to minimize or reduce losses and/or noise in a signal path 422.

The diversity RX module 100 can be configured such that switches 410 and 412, as well as LNAs 414, are implemented in a semiconductor die (depicted as 104) that is mounted underneath a packaging substrate. Filters 400 can be mounted on such a packaging substrate as described herein.

As further shown in FIG. 18, RX signals processed by the diversity RX module 100 can be routed to a transceiver through a signal path 424. In wireless applications where the signal path 424 is relatively long and lossy, the foregoing implementation of the diversity RX module 100 close to the antenna 420 can provide a number of desirable features.

FIG. 19 shows that in some embodiment a dual-sided package having one or more features as described herein can be implemented in other types of LNA applications. For example, in an example wireless device 500 of FIG. 19, an LNA or LNA-related module 100 can be implemented as a dual-sided package as described herein, and such a module can be utilized with a main antenna 524.

The example LNA module 100 of FIG. 19 can include, for example, one or more LNAs 104, a bias/logic circuit 432, and a band-selection switch 430. Some or all of such circuits can be implemented in a semiconductor die that is mounted under a packaging substrate of the LNA module 100. In such an LNA module, some or all of duplexers 400 can be mounted on the packaging substrate so as to form a dual-sided package having one or more features as described herein.

FIG. 19 further depicts various features associated with the example wireless device 500. Although not specifically shown in FIG. 19, a diversity RX module 100 of FIG. 18 can be included in the wireless device 500 with the LNA module 100, in place of the LNA module 100, or any combination thereof. It will also be understood that a dual-sided package having one or more features as described herein can be implemented in the wireless device 500 as a non-LNA module.

In the example wireless device 500, a power amplifier (PA) circuit 518 having a plurality of PAs can provide an amplified RF signal to a switch 430 (via duplexers 400), and the switch 430 can route the amplified RF signal to an antenna 524. The PA circuit 518 can receive an unamplified RF signal from a transceiver 514 that can be configured and operated in known manners.

The transceiver 514 can also be configured to process received signals. Such received signals can be routed to the LNA 104 from the antenna 524, through the duplexers 400. Various operations of the LNA 104 can be facilitated by the bias/logic circuit 432.

The transceiver 514 is shown to interact with a baseband sub-system 510 that is configured to provide conversion between data and/or voice signals suitable for a user and RF signals suitable for the transceiver 514. The transceiver 514 is also shown to be connected to a power management component 506 that is configured to manage power for the operation of the wireless device 500. Such a power management component can also control operations of the baseband sub-system 510.

The baseband sub-system 510 is shown to be connected to a user interface 502 to facilitate various input and output of voice and/or data provided to and received from the user. The baseband sub-system 510 can also be connected to a memory 504 that is configured to store data and/or instructions to facilitate the operation of the wireless device, and/or to provide storage of information for the user.

A number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS.

### General Comments

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A packaged radio-frequency (RF) device comprising:
a packaging substrate configured to receive a plurality of components, the packaging substrate including a first side and a second side;
a shielded package implemented on the first side of the packaging substrate, the shielded package including an RF circuit, the shielded package configured to provide RF shielding for at least a portion of the RF circuit;
a ball-grid array (BGA) implemented on the second side of the packaging substrate, the BGA defining a mounting volume on the second side of the packaging substrate; and
a component implemented within the mounting volume.

2. The device of claim 1 wherein the first and second sides of the packaging substrate correspond to upper and lower sides, respectively, when the packaged RF device is oriented to be mounted on a circuit board.

3. The device of claim 2 wherein the BGA is configured to allow the packaged RF device to be mounted on the circuit board.

4. The device of claim 3 wherein the BGA includes a first group of solder balls arranged to partially or fully surround the component mounted on the lower side of the packaging substrate.

5. The device of claim 4 wherein the BGA further includes a second group of solder balls arranged to partially or fully surrounds the first group of solder balls.

6. The device of claim 5 wherein at least some of the first group of solder balls are electrically connected to input and output nodes of the RF circuit.

7. The device of claim 6 wherein the second group of solder balls are electrically connected to a ground plane within the packaging substrate.

8. The device of claim 7 wherein the first group of solder balls forms a rectangular perimeter around the component mounted on the lower side of the packaging substrate.

9. The device of claim 8 wherein the second group of solder balls forms a rectangular perimeter around the first group of solder balls.

10-12. (canceled)

13. The device of claim 2 wherein the shielded package includes an overmold structure that substantially encapsulates the RF circuit.

14. The device of claim 13 wherein the shielded package further includes an upper conductive layer implemented on the overmold structure, the upper conductive layer electrically connected to a ground plane within the packaging substrate.

15. The device of claim 14 wherein the electrical connection between the upper conductive layer and the ground plane is achieved through one or more conductors within the overmold structure.

16. The device of claim 15 wherein the one or more conductors include shielding wirebonds arranged relative to the RF circuit to provide RF shielding functionality for at least a portion of the RF circuit.

17. The device of claim 15 wherein the one or more conductors include one or more SMT devices mounted on the packaging substrate, the one or more SMT devices arranged relative to the RF circuit to provide RF shielding functionality for at least a portion of the RF circuit.

18. The device of claim 14 wherein the electrical connection between the upper conductive layer and the ground plane is achieved through a conformal conductive coating implemented on one or more sides of the overmold structure.

19. The device of claim 18 wherein the conformal conductive coating extends to corresponding one or more sides of the packaging substrate.

20. The device of claim 19 wherein the packaging substrate includes one or more conductive features each having a portion exposed at the corresponding side of the packaging substrate to form an electrical connection with the conformal conductive coating, each conductive feature further connected to the conductive plane within the substrate packaging.

21. The device of claim 20 wherein the upper conductive layer is a conformal conductive layer.

22-27. (canceled)

28. A method for manufacturing packaged radio-frequency (RF) devices, the method comprising:
providing a packaging substrate configured to receive a plurality of components, the packaging substrate including a first side and a second side;
forming a shielded package on the first side of the packaging substrate, the shielded package including an RF circuit, the shielded package configured to provide RF shielding for at least a portion of the RF circuit;
mounting a component on the second side of the packaging substrate; and
arranging a ball-grid array (BGA) on the second side of the packaging substrate such that the BGA is positioned relative to the component.

29. A wireless device comprising:
a circuit board configured to receive a plurality of packaged modules; and
a shielded radio-frequency (RF) module mounted on the circuit board, the RF module including a packaging substrate configured to receive a plurality of components, the packaging substrate including a first side and a second side, the RF module further including a shielded package implemented on the first side of the packaging substrate, the shielded package including an RF circuit, the shielded package configured to provide RF shielding for at least a portion of the RF circuit, the RF module further including a ball-grid array (BGA) implemented on the second side of the packaging substrate, the BGA defining a mounting volume on the second side of the packaging substrate, the RF module further including a component implemented within the mounting volume.

30-39. (canceled)
